(19) United States
(12) Patent Application Publication
(10) Pub. No.: US 2006/0172545 A1
(43) Pub. Date: Aug. 3, 2006

(54) Purge process conducted in the presence of a purge plasma

(75) Inventors: Kenneth A. Hewes, Richardson, TX (US); Mark D. Odom, Whitehouse, TX (US); Michael J. Satterfield, Richardson, TX (US); Sirisha Kuchimanchi, Plano, TX (US); Sean M. Collins, Richardson, TX (US); Zaid Nahas, Flower Mound, TX (US)

Correspondence Address: TEXAS INSTRUMENTS INCORPORATED, P O BOX 655474, M/S 3999, DALLAS, TX, 75265, US

(73) Assignee: Texas Instruments, Inc., Dallas, TX (US)

(21) Appl. No.: 11/049,198

(22) Filed: Feb. 2, 2005

(51) Int. Cl. C23F 1/00; H01L 21/302; C23C 16/00

(52) U.S. Cl. 438/710; 216/67; 156/345.47; 118/723 E

(57) ABSTRACT

The present invention provides, in one embodiment, a method for reducing defects associated with a plasma deposition or etching process. In this particular embodiment, the method includes creating a plasma in a deposition or etching chamber (140) and purging undesirable species from the deposition or etching chamber (150) in the presence of the plasma.

### TECHNICAL FIELD OF THE INVENTION

The present invention is directed in general to a purge process for use in a deposition or etch chamber and, more specifically, to a purge process conducted in the presence of a purge plasma for use in a deposition or etch chamber.

### BACKGROUND

Manufacturers of microelectronic components use a variety of processing techniques to fabricate semiconductor devices. One technique that has many applications (e.g., deposition, etching, cleaning, and annealing) is known as “plasma-assisted” or “plasma-enhanced” processing. Plasma-enhanced processing is a dry processing technique in which a substantially ionized gas, usually produced by a high-frequency (e.g., 13.56 MHz) electrical discharge, generates active, metastable neutral and ionic species that chemically or physically react to deposit thin material layers on or to etch material layers from semiconductor substrates in a fabrication reactor.

Various applications for plasma-enhanced processing in semiconductor device manufacturing may include high-rate reactive-ion etching (RIE) of thin films of polysilicon, metal, oxides, nitrides, and polyimides; dry development of photoresist layers; plasma-enhanced chemical-vapor deposition (PECVD) of dielectrics, silicon, aluminum, copper, and other materials; planarized inter-level dielectric formation, including procedures such as biased sputtering; and low-temperature epitaxial semiconductor growth processes.

While “plasma-assisted” or “plasma-enhanced” processing is widely used, improvements therein are nevertheless desired. Accordingly, what is needed in the art is an improved method for “plasma-assisted” or “plasma-enhanced” processing that does not suffer from the disadvantages associated with the prior art.

### SUMMARY OF INVENTION

To address the above-discussed deficiencies of the prior art, the present invention provides, in one embodiment, a method for reducing defects associated with a plasma deposition or etching process. In this particular embodiment, the method includes creating a plasma in a deposition or etching chamber and purging undesirable species from the deposition or etching chamber in the presence of the plasma.

In another embodiment, the present invention provides a method for manufacturing an integrated circuit. In this aspect of the present invention, the method includes forming transistor devices over a substrate, wherein forming transistor includes (1) plasma depositing or etching a material layer in the presence of a depositing or etching plasma in a deposition or etching chamber, (2) creating a purging plasma in the deposition or etching chamber after plasma depositing or etching the material layer, and (3) purging undesirable species from the deposition or etching chamber in the presence of the purging plasma. The method further includes forming interconnects within dielectric layers located over the transistor devices to form an operational integrated circuit.

The foregoing has outlined preferred and alternative features of the present invention so that those of ordinary skill in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the scope of the invention.

### BRIEF DESCRIPTION OF THE DRAWINGS

The invention is best understood from the following detailed description when read with the accompanying FIGURES. It is emphasized that in accordance with the standard practice in the semiconductor industry, various features may not be drawn to scale. In fact, the dimensions of the various features may be arbitrarily increased or reduced for clarity of discussion. Reference is now made to the following descriptions taken in conjunction with the accompanying drawings, in which:

FIG. 1 illustrates a flow chart depicting steps that might be used to reduce defects associated with a plasma deposition process;

FIG. 2 illustrates a schematic cross-sectional view of a plasma deposition tool that might be used to reduce defects associated with a plasma deposition process in accordance with the principles of the present invention; and

FIG. 3 illustrates a cross-sectional view of an integrated circuit (IC) incorporating devices manufactured in accordance with the principles of the present invention.

### DETAILED DESCRIPTION

The present invention is based, at least in part, on the unique recognition that undesirable species left in a plasma deposition or etching chamber following the plasma deposition or etching of a material layer, but after turning off the plasma, tend to cause unwanted defects. It has particularly been observed that silane, left in the plasma deposition or etching chamber after turning off the plasma and while purging the plasma deposition or etching chamber, tends to fall or alternatively be attracted to the material layer, and thereby tends to cause defects under/on/over the material layer during subsequent processing steps.

With this recognition, the present invention acknowledged that maintaining a plasma during the purging process (e.g., in one instance leaving the RF on in the presence of an inert gas needed to strike a plasma during the purging process) substantially reduced the defects caused by the undesirable species. This process is drastically different from conventional processes, where both the RF and all process gases (i.e., the plasma) are turned off during the purging process. It is believed that there is a subtle timing issue with both the RF and process gases turning off at the same time, resulting in some form of unreacted undesirable species from the process gas falling onto the material layer when the plasma collapses. Leaving a plasma on during the purging process either causes all of the unreacted undesirable species to react and be purged out of the plasma deposition or etching chamber, or alternatively a columbic repulsion between the unreacted undesirable species and the material layer, wherein the unreacted undesirable species are again purged out of the plasma deposition or etching chamber. In any event, a substantially reduced number of defects are observed when the plasma remains on during the purging process. It is important, however, that the plasma that remains on during the purging process not introduce undesirable species back into the plasma deposition or etching chamber.

It should initially be noted that while the present invention will now be discussed with respect to a plasma deposition process, those skilled in the art understand that the present invention is equally applicable to a plasma etching process, without departing from the scope of the present invention. Therefore, the plasma deposition process discussed below should not be used to limit the scope of the present invention. It should also be noted that the term undesirable species, as used herein, without limitation refers to any species of particulate, gaseous or liquid matter that is capable of creating defects during the plasma deposition or etching of a material layer, and is thus undesirable.

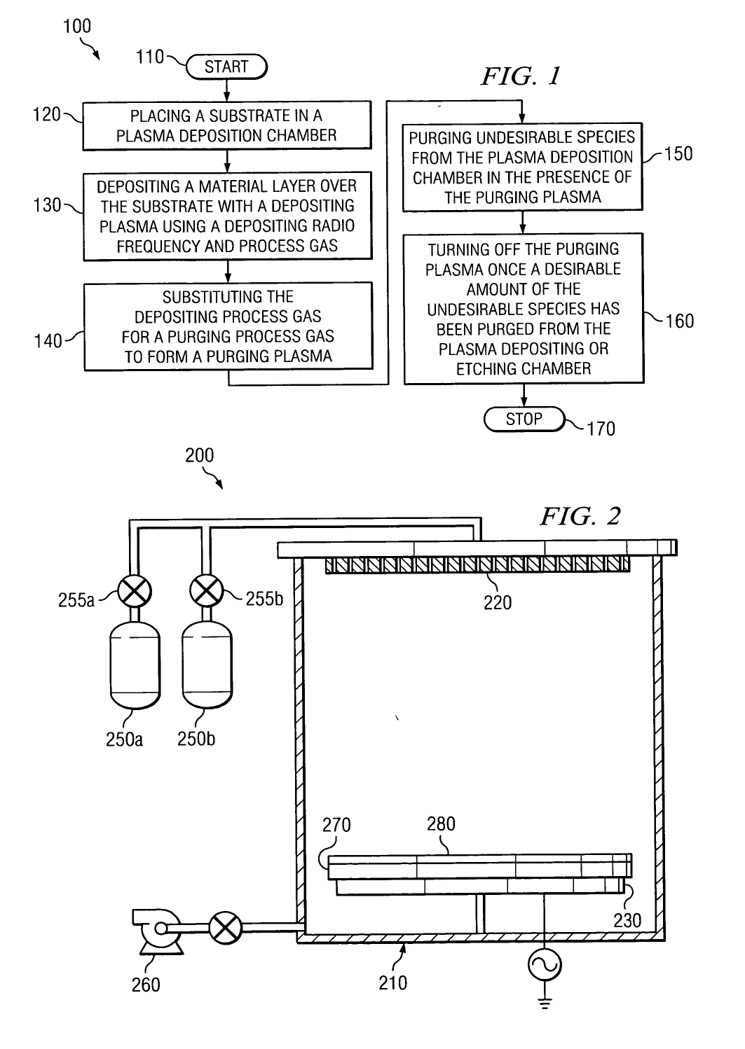

Referring initially to FIG. 1, illustrated is a flow chart 100 depicting steps that might be used to reduce defects associated with a plasma deposition process. While the flow chart 100 is depicted as having only five main steps, those skilled in the art understand that the plasma deposition process may, and most times will, encompass more steps than depicted in FIG. 1. Additionally, as the flow chart 100 sets forth the steps that might be used to deposit a material layer, the collection of steps could be repeated any number of times to deposit any number of material layers, without departing from the scope of the present invention.

Turning now to FIG. 2 illustrated is a schematic cross-sectional view of a plasma deposition tool 200 that might be used to reduce defects associated with a plasma deposition process in accordance with the principles of the present invention. In the embodiment shown and discussed with respect to FIG. 2, the plasma deposition tool 200 contains a plasma deposition chamber 210. In the particular embodiment shown and discussed, the plasma deposition chamber 210 comprises a plasma enhanced chemical vapor deposition (PECVD) chamber that might be used to deposit an inorganic anti-reflective coating (IARC) or hardmask. Other types of plasma deposition chambers could nonetheless be used.

Located within the plasma deposition chamber 210 of the plasma deposition tool 200 will typically be a showerhead electrode 220 mounted on a top wall thereof. Gas entering an RF field formed between the electrodes is converted into ionized chemical species. Further located within the plasma deposition chamber 210 is a heater or pedestal 230. In the embodiment illustrated in FIG. 2, the heater or pedestal 230 is mounted parallel to and spaced from the showerhead electrode 220. As those skilled in the art are aware, a source of RF power would typically be connected to the showerhead electrode.

Further connected to the plasma deposition chamber 210 are gas sources 250a, 250b. The gas flows from the gas sources 250a, 250b may be metered to the plasma deposition chamber 210 by means of Mass Flow Controllers (MFC) 255a, 255b, respectively. Additionally, connected to the plasma deposition chamber 210 is a pump 260. The pump 260, such as a roughing pump, maintains a desired pressure in the plasma deposition chamber 210, as well as purges the plasma deposition chamber 210 when desired.

Referring again to FIG. 1, with brief references to FIG. 2, a method for reducing defects associated with a plasma deposition process in accordance with the principles of the present invention, is discussed. The method for reducing defects associated with a plasma deposition process begins in a start step 110. After the start step 110, in a step 120, a substrate 270 is placed within the plasma deposition tool 200. In the particular embodiment shown and discussed with respect to FIG. 2, the substrate 270 is placed within the plasma deposition chamber 210 of the plasma deposition tool 200.

The substrate 270 may comprise a variety of different materials and configurations while staying within the scope of the present invention. For example, the substrate 270 could be a polysilicon gate electrode layer, an interlevel dielectric layer of an integrated circuit, or another similar layer. Additionally, the substrate 270 need not be a flat surface, and hence could have an opening formed therein, such as a via or trench in the interlevel dielectric layer.

After step 120, in a step 130, a material layer 280 may be formed over the substrate 270 while in the plasma deposition chamber 210. The material layer 280 may comprise a number of different materials, however, in the exemplary embodiment discussed with respect to FIGS. 1 and 2 the material layer 280 comprises an inorganic anti-reflective coating (IARC) or hardmask.

The material layer 280 may be formed using a number of different conventional manufacturing parameters and stay within the purview of the present invention. Nevertheless, in one advantageous embodiment the material layer 280 is formed using a conventional depositing plasma, thus using a depositing RF and a depositing process gas. As one would expect, the depositing RF is created by connecting an RF power source to the showerhead electrode 220. Similarly, the depositing process gas is introduced using the gas source 250a and MFC 255a. The depositing process gas, among others, often contains silane therein. In addition to the depositing RF and depositing process gas, other parameters, such as spacing and pressure may be tailored. As the remainder of the process for forming the material layer 280 is conventional, no further discussion is given.

After forming the material layer 280 in the step 130, the depositing plasma may be substituted for a purging plasma, in a step 140. While a number of different steps may be taken to substitute the depositing plasma for the purging plasma, one embodiment has the depositing process gas being turned off at substantially the same time as the purging process gas is turned on. The purging process gas, among other conceivable choices, may comprise any process gas capable of maintaining the purging plasma that does not contain undesirable species that may form the aforementioned defects. In one exemplary embodiment, the purging process gas is an inert gas, such as helium, hydrogen, or argon. Other purging process gases may nonetheless be used. As one skilled in the art would appreciate, the gas source 250b and flow control 255b may be used to introduce the purging process gas.

To accomplish this, the depositing RF may stay on and thus just turn into a purging RF when the purging process gas enters the plasma deposition chamber 210. It is often the case where the depositing RF and purging RF are substantially identical. Regardless of circumstances, it is strongly desired that the purging plasma is continuous with the depositing plasma. If it is not, there is a chance that certain ones of the undesirable species will fall to the material layer 280 and ultimately form a defect.

After forming the purging plasma in the step 140, undesirable species located within the plasma deposition chamber 210, or anywhere in the plasma deposition tool 200, are removed therefrom in the presence of the purging plasma. As indicated above, this allows the undesirable species to exit the plasma deposition tool 200 without creating the aforementioned defects. Those skilled in the art understand the variety of mechanisms that might be used to purge the undesirable species, including the pump 260. Other conceivable mechanisms, not discussed, could also be used to remove the undesirable species.

Thereafter, in a step 160, the purging plasma may be turned off after a desirable amount of undesirable species has been purged from the plasma deposition chamber 210. In an exemplary embodiment, the purging plasma remains on until substantially all of the undesirable species has been removed from the plasma deposition chamber 210. As one would expect, the purging plasma may be turned off by stopping providing the purging RF, purging process gas, or both. After completing step 160, the unique process of the present invention could end in a stop step 170, or could go back to step 120 for the deposition of another material layer 280.

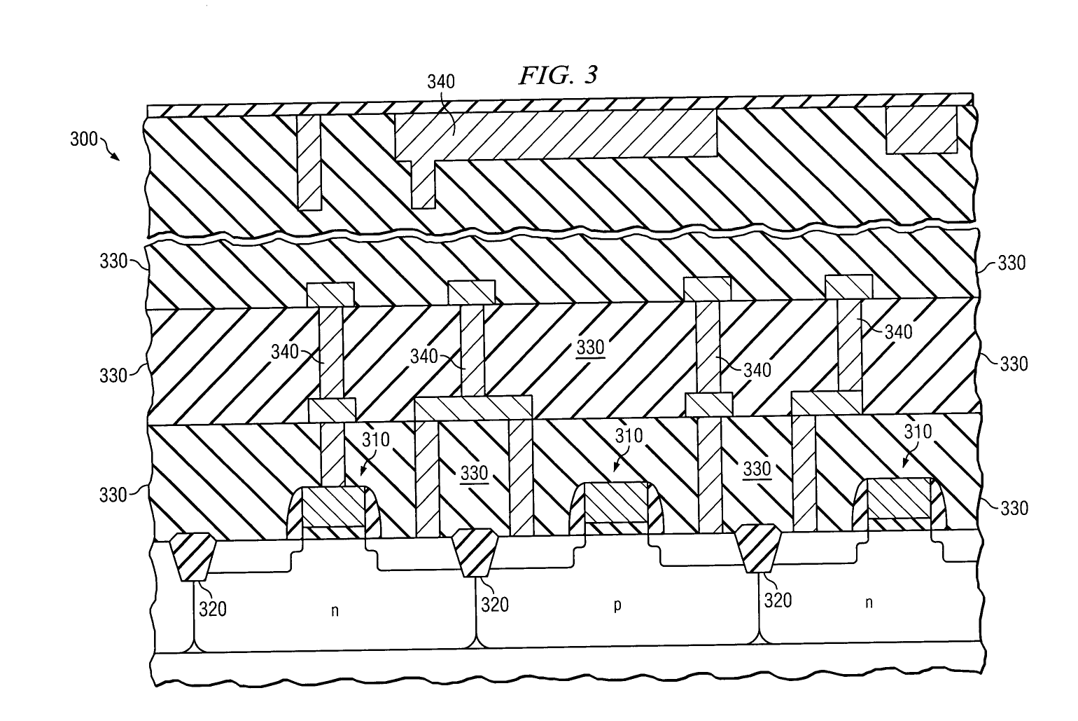

Referring finally to FIG. 3, illustrated is a cross-sectional view of an integrated circuit (IC) 300 incorporating devices manufactured in accordance with the principles of the present invention. The IC 300 may include devices, such as transistors used to form CMOS devices, BiCMOS devices, Bipolar devices, or other types of devices. The IC 300 may further include passive devices, such as inductors or resistors, or it may also include optical devices or optoelectronic devices. Those skilled in the art are familiar with these various types of devices and their manufacture.

In the particular embodiment illustrated in FIG. 3, the IC 300 includes transistor devices 310 located between isolation structures 320. The IC 300 of FIG. 3 further includes dielectric layers 330 located over the transistor devices 310. In accordance with the principles of the present invention, interconnects 340 are located within the dielectric layers 330. The devices of the IC 300, as those skilled in the art are aware, may be manufactured using the method for reducing defects associated with a plasma deposition or etching process discussed above with respect to FIGS. 1-2.

Although the present invention has been described in detail, those skilled in the art should understand that they can make various changes, substitutions and alterations herein without departing from the spirit and scope of the invention in its broadest form.

What is claimed is:

1. A method for reducing defects associated with a plasma deposition or etching process, comprising:
creating a plasma in a deposition or etching chamber; and
purging undesirable species from the deposition or etching chamber in the presence of the plasma.

2. The method as recited in claim 1 wherein the undesirable species is silane.

3. The method as recited in claim 1 wherein the plasma is a purging plasma and the method further includes creating a depositing or etching plasma prior to creating the purging plasma.

4. The method as recited in claim 3 wherein the purging plasma and depositing or etching plasma are continuous.

5. The method as recited in claim 3 wherein the purging plasma uses a purging radio frequency and a purging process gas and the depositing or etching plasma uses a depositing or etching radio frequency and a depositing or etching process gas.

6. The method as recited in claim 5 wherein the purging process gas is an inert gas.

7. The method as recited in claim 6 wherein the purging process gas includes helium.

8. The method as recited in claim 5 wherein the purging radio frequency and the depositing or etching radio frequency are substantially similar.

9. The method as recited in 8 wherein the depositing or etching process gas is substituted for the purging process gas.

10. The method as recited in claim 1 further including stopping the plasma after substantially all of the undesirable species are removed from the deposition or etching chamber.

11. A method for manufacturing an integrated circuit, comprising:
forming transistor devices over a substrate, including;
plasma depositing or etching a material layer in the presence of a depositing or etching plasma in a deposition or etching chamber;
creating a purging plasma in the deposition or etching chamber after plasma depositing or etching the material layer; and
purging undesirable species from the deposition or etching chamber in the presence of the purging plasma; and
forming interconnects within dielectric layers located over the transistor devices to form an operational integrated circuit.

12. The method as recited in claim 11 wherein the undesirable species is silane.

13. The method as recited in claim 11 wherein the purging plasma and depositing or etching plasma are continuous.

14. The method as recited in claim 11 wherein the purging plasma uses a purging radio frequency and a purging process gas and the depositing or etching plasma uses a depositing or etching radio frequency and a depositing or etching process gas.

15. The method as recited in claim 14 wherein the purging process gas is an inert gas.

16. The method as recited in claim 15 wherein the purging process gas includes helium.

17. The method as recited in claim 15 wherein the purging radio frequency and the depositing or etching radio frequency are substantially similar.

18. The method as recited in 17 wherein the depositing or etching process gas is substituted for the purging process gas.

19. The method as recited in claim 11 further including stopping the purging plasma after substantially all of the undesirable species are removed from the deposition or etching chamber.
